(19) United States
(12) Patent Application Publication
(10) Pub. No.: US 2024/0412949 A1
(43) Pub. Date: Dec. 12, 2024

(54) Remote Plasma Device and Plasma Processing Apparatus

(71) Applicant: Tokyo Electron Limited, Tokyo (JP)

(72) Inventors: Taro IKEDA, Yamanashi (JP); Eiki KAMATA, Yamanashi (JP); Kenta KATO, Yamanashi (JP)

(21) Appl. No.: 18/674,349

(22) Filed: May 24, 2024

(30) Foreign Application Priority Data
Jun. 6, 2023 (JP) 2023-093239

(51) Int. Cl. H01J 37/32; H01J 37/34

(52) U.S. Cl. CPC H01J 37/32357; H01J 37/3244; H01J 37/3488

(57) ABSTRACT

There is a remote plasma device comprising: a housing made of a metal; a dielectric disposed to fill the housing; a gas supply port disposed at the housing, and configured to supply a gas into the housing; a gas exhaust port disposed at the housing, and configured to discharge the gas from the housing; a gas line that is formed in the dielectric and connects the gas supply port and the gas discharge port; and an electromagnetic wave supply part disposed at the housing, and configured to supply electromagnetic waves into the housing and produce plasma in the gas line.

### CROSS-REFERENCE TO RELATED APPLICATIONS

This application claims priority to Japanese Patent Application No. 2023-093239 filed on Jun. 6, 2023, the entire contents of which are incorporated herein by reference.

### TECHNICAL FIELD

The present disclosure relates to a remote plasma device and a plasma processing apparatus.

### BACKGROUND

For example, Japanese Laid-open Patent Publication No. 2014-49529 proposes a plasma processing apparatus including an inductively coupled remote plasma unit. The remote plasma unit is an inductively coupled plasma source, and defines a plasma generation space above a processing space of a plasma processing apparatus. The remote plasma unit has a coil surrounding the plasma generation space, and a radio frequency (RF) power supply for supplying an RF power is connected to the coil.

### SUMMARY

The present disclosure provides a technique capable of scaling down a remote plasma device.

In accordance with an exemplary embodiment of the present disclosure, there is a remote plasma device comprising: a housing made of a metal; a dielectric disposed to fill the housing; a gas supply port disposed at the housing, and configured to supply a gas into the housing; a gas exhaust port disposed at the housing, and configured to discharge the gas from the housing; a gas line that is formed in the dielectric and connects the gas supply port and the gas discharge port; and an electromagnetic wave supply part disposed at the housing, and configured to supply electromagnetic waves into the housing and produce plasma in the gas line.

### BRIEF DESCRIPTION OF THE DRAWINGS

FIG. 1 is a cross-sectional view showing an example of a plasma processing apparatus according to an embodiment.

FIGS. 2A and 2B are cross-sectional perspective views showing an example of a remote plasma device according to an embodiment.

FIGS. 3A and 3B show a horizontal cross section and a vertical cross section of a remote plasma device according to an embodiment, respectively.

FIG. 4 shows an example of frequency characteristics of an antenna impedance according to an embodiment.

FIGS. 5A and 5B show examples of electric field in a dielectric during ignition according to an embodiment.

FIGS. 6A and 6B showing an example of the relationship between a length of a reflection antenna and an electric field strength according to an embodiment.

FIG. 7 shows a modification of a reflection antenna according to an embodiment.

### DETAILED DESCRIPTION

Hereinafter, embodiments of the present disclosure will be described in detail with reference to the accompanying drawings. Like reference numerals will be given to like parts throughout the drawings, and redundant description thereof may be omitted.

In this specification, directions such as parallel, right-angled, orthogonal, horizontal, vertical, up and down, and left and right are allowed to deviate without spoiling the effect of the embodiment.

### (Plasma Source Using ICP Plasma)

In a plasma processing apparatus, particularly, a small and efficient remote plasma device (plasma source) used as a remote source is required. In order to efficiently generate plasma, a space of λg/2 is required (λg being a guide wavelength). In the case of inductively coupled plasma (ICP), a frequency of a radio frequency (RF) power supplied to a coil is about 27 MHz at most, which is low, so the guide wavelength λg increases to a certain extent. Therefore, in the case of using ICP, the device is structurally large, which makes it difficult to scale down the remote plasma device.

Hence, microwaves with a frequency higher than 27 MHz are supplied to the coil. An impedance expressed as ωL (ω: angular frequency (ω=2πf (f: frequency)), L: coil inductance) increases as the frequency f increases, and a voltage applied to the coil increases, so the dielectric around the coil is hit by ions and damaged. Therefore, high-frequency microwaves cannot be supplied to the ICP coil.

When the size of the remote plasma device itself increases, the remote plasma device may not be assembled to a predetermined space of a plasma processing apparatus. In addition, the cost of manufacturing the remote plasma device tends to be high.

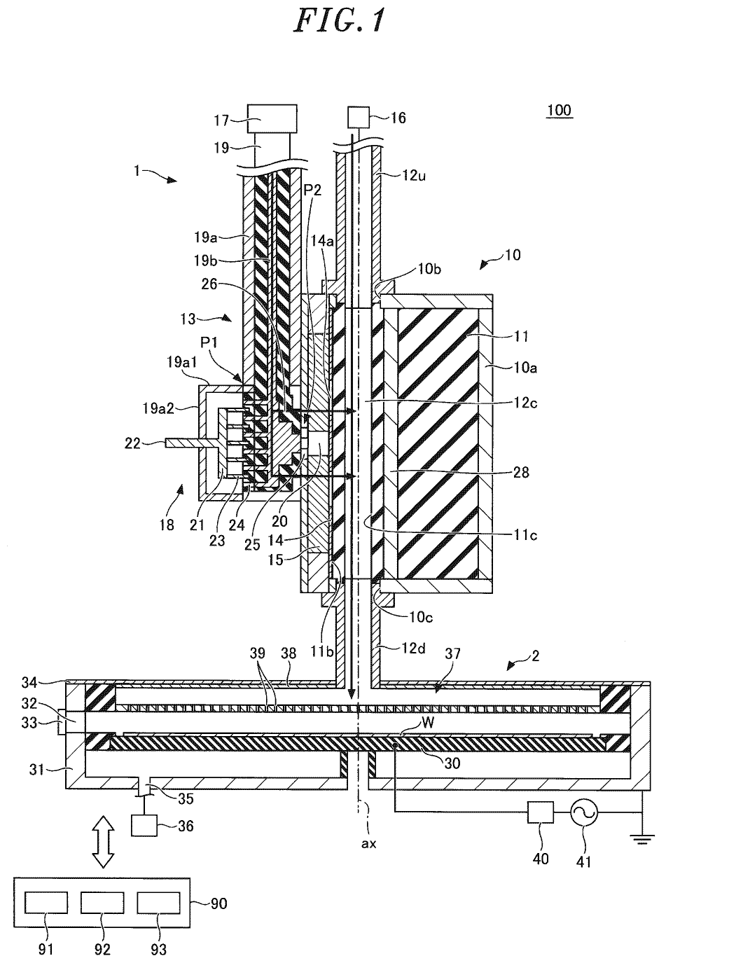

Therefore, in the present embodiment, the remote plasma device is scaled down by using high-frequency microwaves. Accordingly, there is proposed a remote plasma device that is easily assembled to the plasma processing apparatus. Hereinafter, the plasma processing apparatus to which the remote plasma apparatus of the present embodiment is assumed will be described with reference to FIGS. 1 to 3.

### (Plasma Processing Apparatus)

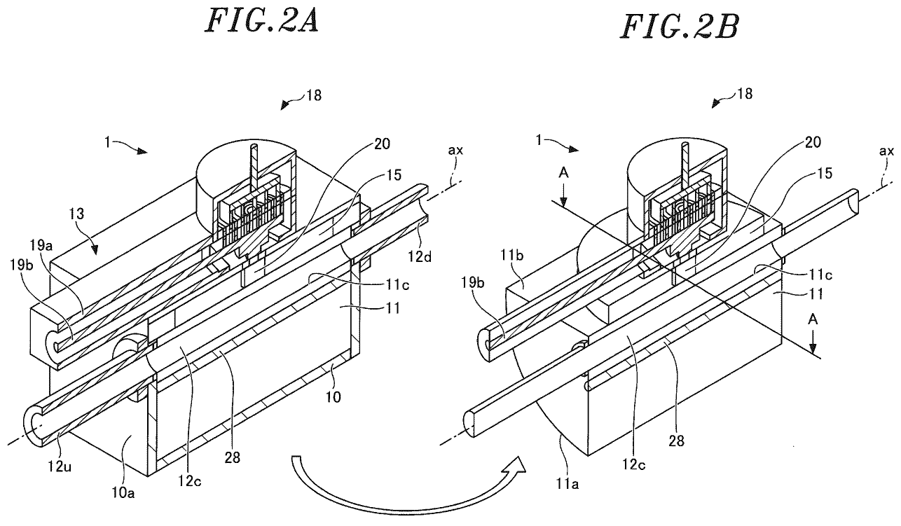

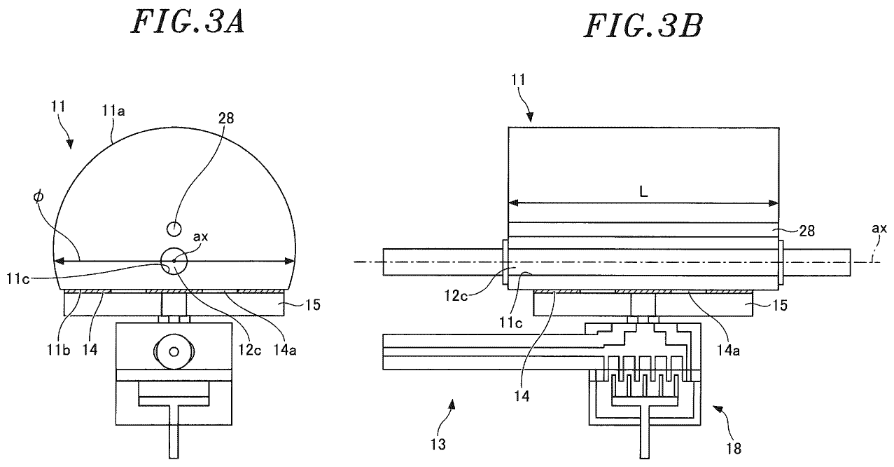

FIG. 1 is a cross-sectional view showing an example of a vertical cross section of a plasma processing apparatus 100 according to an embodiment. FIGS. 2A and 2B are cross-sectional perspective view showing an example of a remote plasma device 1 according to an embodiment. FIGS. 3A and 3B show a horizontal cross section (taken along a line A-A of FIG. 2B) and a vertical cross section of the remote plasma device 1 according to an embodiment, respectively.

The plasma processing apparatus 100 includes the remote plasma device 1 and a plasma processing chamber 2. The remote plasma device 1 includes a metal housing 10, a dielectric 11, a gas line 12c, and an electromagnetic wave supply part 13.

The metal housing 10 is made of a metal (conductor) such as aluminum, for example. As shown in FIG. 2A, the housing 10 has a rectangular outer shape.

The dielectric 11 is disposed to fill the inside of the housing 10. The dielectric 11 is made of aluminum nitride (AlN), for example. The inner shape of one surface 10a of the housing 10 has an imperfect/deficient cylindrical shape that is a substantially semi-cylindrical shape. Therefore, as shown in FIG. 2B in which the housing 10 of FIG. 2A is omitted for convenience and FIG. 3A in which the cross section taken along the A-A plane of FIG. 2B is turned upside down, the dielectric 11 disposed to fill the housing 10 has an imperfect cylindrical shape. The dielectric 11 has a flat surface 11b formed by cutting a part of the cylindrical side surface 11a.

The gas line 12c is disposed at a position (a center position on the assumption that the dielectric 11 has a circular cross section) of a center axis ax of the dielectric 11 shown in FIGS. 1 to 3. The housing 10 has a gas supply port 10b for supplying a gas into the housing 10, and a gas exhaust port 10c for discharging a gas from the housing 10.

As shown in FIGS. 1 to 3, an upper gas supply line 12u, a lower gas supply line 12d, and a gas line 12c are disposed at the center axis ax of the dielectric 11. The upper gas supply line 12u is connected to the gas supply part 16. The upper gas supply line 12u is fitted to the gas supply port 10b formed at the housing 10. The lower gas supply line 12d is fitted to the gas exhaust port 10c formed at the housing 10. The gas line 12c is made of the dielectric 11, penetrates through the dielectric 11, and connects the gas supply port 10b and the gas discharge port 10c. In other words, the gas line 12c is a through-hole 11c penetrating through the dielectric 11. The inner spaces of the upper gas supply line 12u, the lower gas supply line 12d, and the gas line 12c are maintained in a vacuum state, and plasma is produced in the gas line 12c as will be described later. In other words, the inner space of the gas line 12c serves as a plasma generation space.

The electromagnetic wave supply part 13 is disposed at the housing 10, and is configured to supply electromagnetic waves into the housing 10 and produce plasma in the gas line 12c. In the present embodiment, the electromagnetic wave supply part 13 supplies microwaves of 860 MHz as an example of electromagnetic waves.

A slot antenna 14 is disposed along the flat surface 11b formed at the dielectric 11 in the housing 10. As shown in FIG. 1, the slot antenna 14 is a thin metal plate disposed between a disc-shaped quartz member 15 and a dielectric 11 in the housing 10. The slot antenna 14 has a ring-shaped slot 14a (space), and radiates microwaves from the slot 14a. The microwaves radiated from the slot 14a pass through the dielectric 11 and are supplied into the gas line 12c. Accordingly, the gas outputted from the gas supply part 16 and introduced from the gas supply port 10b is decomposed by the energy of the microwaves, thereby producing plasma in the gas line 12c. The plasma can be efficiently produced in the plasma generation space in the gas line 12c by providing the slot antenna 14 near the gas line 12c.

The electromagnetic wave supply part 13 is disposed on one surface of the housing 10 on the flat surface 11b side of the dielectric 11, and includes a microwave output part 17 and a resonator 18. The microwave output part 17 outputs microwaves. The resonator 18 guides the microwaves outputted from the microwave output part 17 to the slot antenna 14. The microwave output part 17 has a microwave oscillator. The microwave oscillator may be of a magnetron type or a solid state type. The frequency of the microwaves generated by the microwave oscillator is within a range of, e.g., 300 MHz and 3 THz. For example, the microwave output part 17 outputs microwaves of 860 MHz using a magnetron type microwave oscillator. Further, the microwave output part 17 may be an oscillator that oscillates electromagnetic waves in an ultra high frequency (UHF) band.

A waveguide 19 has a coaxial structure including an outer conductor 19a and an inner conductor 19b, and a dielectric such as poly tetra fluoro ethylene (PTFE) fills the gap between the outer conductor 19a and the inner conductor 19b. The resonator 18 is connected to the microwave output part 17 via the waveguide 19, and is connected to the slot antenna 14 via a power feeding part 20.

The resonator 18 has a function of matching an impedance of a load (plasma) in the housing 10 with an output impedance of the microwave output part 17. Further, a mode conversion mechanism is omitted because the resonator 18 has the same function between the microwave output part 17 and the power supply part 20. The waveguide 19 guides the microwaves outputted from the microwave output part 17 to the resonator 18. The power feeding part 20 is connected to the center of the slot antenna 14. The microwaves outputted from the microwave output part 17 pass through the resonator 18 and the power feeding part 20, and then are radiated into the plasma generation space in the gas line 12c via the slot 14a of the slot antenna 14 and the dielectric 11.

A part of the outer conductor 19a serves as the housing of the resonator 18, and has a ground potential together with the grounded plasma processing chamber 2. The outer conductor 19a has a cylindrical shape, and an input port P1 is formed on a side surface 19a1 of the resonator 18. In the outer conductor 19a, an output port P2 is formed at the end of the cylindrical body near the position where the input port P1 is formed, and the other end 19a2 is formed in a disc shape to close the cylindrical body. A rod-shaped portion 22 for moving a ground fin 21 in the left-right direction in FIG. 1 is held at the center of the end portion 19a2.

The ground fin 21 is made of a conductor such as aluminum or copper. The ground fin 21 has a plurality of fins 23 and a rod-shaped portion 22. The plurality of fins 23 have, e.g., a concentric columnar shape and a cylindrical shape. Further, the plurality of fins 23 have a comb-shape in the cross section shown in FIG. 1.

A plurality of fins 24 are disposed in the housing of the resonator 18. The plurality of fins 24 are triple cylindrical multipole antennas. Further, the plurality of fins 24 have a comb-shape in the cross section shown in FIG. 1.

The inner conductor 19b is connected to the side surfaces of the fins 24. A ring member 25 made of alumina and the power feeding part 20 made of a conductor, which are fitted by boring a part of the housing 10, are disposed near the output port P2. In other words, a power supply line 26 insulated from the housing of the resonator 18 is formed by the inner conductor 19b of the input port P1, the inner conductor 19b of the output port P2, and the fins 24.

Further, the tip ends of the plurality of fins 24 are covered with a dielectric such as PTFE. The ground fin 21 is slidable, and is not brought into contact with the fins 24 even when the ground fin 21 is inserted into the innermost fin 24. The fins 23 of the ground fin 21 move along the dielectric such as PTFE when the amount of insertion into the fins 24 is changed. In this manner, the frequency (resonant frequency) passing through the resonator 18 can be modified by changing the insertion amount of the ground fin 21 and changing the dimension of the resonant space.

From the above, the resonator 18 is a comb-shaped resonator having comb-shaped fins 23 and 24 on opposing cross sections. The electromagnetic wave supply part 13 may have a comb-shaped resonator, and supply electromagnetic waves into the housing 10 via the comb-shaped resonator and the slot antenna 14. By providing a comb-shaped resonator at the electromagnetic wave supply part 13, the remote plasma device 1 can be further scaled down. However, the electromagnetic wave supply part 13 may not have a comb-shaped resonator. Further, the slot antenna 14 may not be provided. In other words, the electromagnetic wave supply part 13 may supply microwaves into the housing 10 via the waveguide 19.

Active species of the processing gas contained in plasma generated in the gas line 12c of the remote plasma device 1 are supplied into the plasma processing chamber 2 through the lower gas supply line 12d. The plasma processing apparatus 100 may be a thermal chemical vapor deposition (CVD) apparatus for performing heat treatment on a substrate W to be processed in the plasma processing chamber 2. The substrate W to be processed is placed on a placing table 30 in the plasma processing chamber 2. The central axis of the plasma processing chamber 2 coincides with the central axis ax of the remote plasma device 1.

The plasma processing chamber 2 includes a chamber body 31. The chamber body 31 is formed in a cylindrical shape, and has an upper opening, a sidewall, and a bottom portion. The chamber body 31 is made of a metal such as aluminum or the like. The chamber body 31 is grounded. The sidewall of the chamber body 31 provides a passage 32. The substrate W to be processed passes through the passage 32 when it is transferred between the inside and the outside of the plasma processing chamber 2. The passage 32 can be opened and closed by a gate valve 33. The gate valve 33 is disposed along the sidewall of the chamber body 31.

The plasma processing chamber 2 has a top wall 34. The top wall 34 is made of a metal such as aluminum or the like. The top wall 34 closes the upper opening of the chamber body 31. The top wall 34 is grounded together with the chamber body 31.

The bottom portion of the plasma processing chamber 2 provides an exhaust port 35. The exhaust port 35 is connected to an exhaust device 36. The exhaust device 36 includes a pressure controller such as an automatic pressure control valve, and a vacuum pump such as a turbo molecular pump.

The plasma processing chamber 2 has a shower head 37 facing the placing table 30. The shower head 37 is made of a metal such as aluminum or the like. The shower head 37 is formed in a disc shape, and has a gas diffusion space 38 and a plurality of gas holes 39 communicating with the gas diffusion space 38. Accordingly, the active species of the processing gas supplied from the remote plasma device 1 are introduced into the processing space between the shower head 37 and the placing table 30 via the gas diffusion space 38 and the plurality of gas holes 39.

A radio frequency (RF) power supply 41 is connected to the placing table via an impedance matching circuit 40. The impedance matching circuit 40 is configured to match the impedance of the load of the RF power supply 41 with the output impedance of the RF power supply 41. The frequency of the RF power supplied from the RF power supply 41 is lower than the frequency of microwaves. The frequency of the RF power may be, e.g., 13.56 MHz. The RF power supplied from the RF power supply 41 may be supplied to the shower head 37.

In the plasma processing apparatus 100 of the present embodiment, the remote plasma device 1 is small, and thus can be easily assembled to the conventional plasma processing chamber 2. The remote plasma device 1 activates the processing gas slightly compared to that during heat treatment, and supplies the activated species to the plasma processing chamber 2. In other words, the remote plasma device 1 can supply appropriately decomposed active species of the processing gas into the plasma processing chamber 2. Accordingly, it is possible to process the substrate W in the plasma processing chamber 2 by activating the processing gas slightly compared to that during heat treatment.

In the case of performing heat treatment on the substrate W to be processed, the gas supplied to the processing space in the plasma processing chamber 2 is activated by thermal energy and decomposed. For example, in the case of using NH₃ (ammonia) gas for formation of a SiN film or a TiN film, when NH₃ gas is supplied to the gas line 12c, active species such as slightly activated NH₂ and the like are generated from NH₃ gas in the gas line 12c and supplied to the plasma processing chamber 2. In this manner, by controlling the dissociation state of NH₃ using the remote plasma device 1 and supplying active species that are not excessively dissociated to the plasma processing chamber 2, ammonia as a high-quality reducing agent can be supplied. Accordingly, a high-quality film can be formed without impact of ions in the high-density plasma in a state where the temperature of the substrate W to be processed is low.

By using the remote plasma device 1, in the case of activating a reducing agent such as NH₃ gas, the reducing gas is not excessively decomposed. If the reducing gas is excessively decomposed, the reactivity increases and, thus, the active species react prematurely, and hardly reach holes or trenches formed in the film.

In the plasma processing apparatus 100 of the present embodiment, the remote plasma device 1 decomposes a desired gas not excessively but appropriately, and supplies it into the plasma processing chamber 2 so that it can be used for heat treatment of the substrate W to be processed. Accordingly, the temperature of the substrate W can be controlled to a low temperature, and a high-quality film can be formed. Further, even when the RF power supply 41 supplies the RF power having a frequency lower than that of microwaves, the reducing agent can be supplied into the plasma processing chamber 2 in a state where it can be sufficiently dissociated.

A controller 90 processes computer-executable instructions that cause the plasma processing apparatus 100 to perform various steps described in the present disclosure. The controller 90 may be configured to control individual components of the plasma processing apparatus 100 to perform various steps described herein. In one embodiment, the controller 90 may be partially or entirely included in the plasma processing apparatus 100. The controller 90 may include a processing part 91, a storage part 92, and a communication interface 93. The controller 90 is realized by, for example, a computer. The processing part 91 may be configured to read a program from the storage part 92 and perform various control operations by executing the read program. This program may be stored in advance in the storage part 92, or may be obtained via a medium when necessary. The acquired program is stored in the storage part 92, and is read out from the storage part 92 and executed by the processing part 91. The medium may be various computer-readable storage media, or may be a communication line connected to the communication interface 93. The processing part 91 may be a central processing unit (CPU). The storage part 92 may include a random access memory (RAM), a read only memory (ROM), a hard disk drive (HDD), a solid state drive (SSD), or a combination thereof. The communication interface 93 may communicate with the plasma processing apparatus 100 via a communication line such as a local area network (LAN) or the like.

### (Dielectric Resonator)

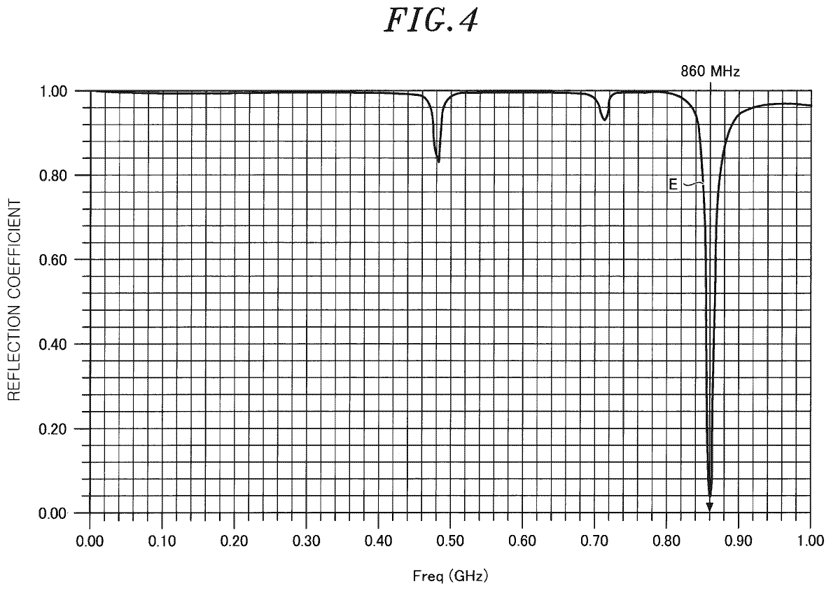

The dielectric 11 functions as a resonator (hereinafter referred to as “dielectric resonator”) that resonates with the microwaves at the frequency supplied by the electromagnetic wave supply part 13. The simulation results of the frequency characteristics of the dielectric resonator (the dielectric 11) will be described with reference to FIG. 4. FIG. 4 shows an example of frequency characteristics of a dielectric resonator according to an embodiment.

In a graph E shown in FIG. 4, the frequency characteristics of the antenna impedance including the plasma load (plasma) in the gas line 12c are expressed by a reflection coefficient. The frequency (resonance frequency), at which the reflection coefficient is minimum, is 860 MHz. This shows that when the microwaves of 860 MHz are supplied, the impedance is extremely high due to the resonance in the dielectric 11, and even if the impedance of the plasma that is the load changes somewhat, the effect of the change on the overall impedance is small.

In this manner, by providing the dielectric resonator (the dielectric 11) near the slot antenna 14, the energy can be efficiently transmitted to the plasma in the gas line 12c. Further, due to the dielectric resonator (the dielectric 11), the remote plasma device 1 can become highly efficient and compact.

A diameter φ (see FIG. 3A) of the dielectric resonator (the dielectric 11) may be calculated as φ=λg/2+δ, where λg is the guide wavelength in the dielectric 11. In this case, 0≤δ≤λg/20 is satisfied, and the diameter φ is equal to or slightly different from λg/2.

Unlike in a free space, the wavelength increases in a circular waveguide that is not a pure circular waveguide, such as the shape of the dielectric resonator (the dielectric 11). The resonance mode adopted here is a TE011 mode that is the fundamental mode of the circular waveguide. A cutoff wavelength λc in the fundamental mode is 3.4125a, where a is the radius (a=φ/2) of the dielectric resonator (the dielectric 11).

Therefore, when a is 4.5 cm, λc becomes 15.35 cm. Accordingly, the guide wavelength λg of the dielectric resonator (the dielectric 11) is expressed by Eq. (1).

$${λ}_{g} = \frac{λ}{\sqrt{1 - {( λ / {λ}_{c} )}^{2}}} = \frac{11.76}{\sqrt{1 - {( 11 \text{.76} / 15.35 )}^{2}}} = 18.3 cm \qquad Eq . ( 1 )$$

Here, the wavelength λ in Eq. (1) is the wavelength of 860 MHz microwaves in the dielectric 11 made of AlN with a relative dielectric constant εᵣ of 8.8. Therefore, in the case of manufacturing the cylindrical dielectric resonator (the dielectric 11) having the diameter φ and the length that are a guide half-wavelength (a half of the guide wavelength), i.e., λg/2=18.3/2=9.2 cm, at 860 MHz, the microwave power can be efficiently absorbed into the plasma.

However, the guide wavelength increases slightly in such a structure in which a part of the cylindrical dielectric resonator (the dielectric 11) is flattened and a metal reflection antenna (conductor) for promoting ignition, which will be described later, is disposed near the gas line 12c (the plasma generation space). Therefore, a desired diameter φ of the dielectric resonator (the dielectric 11) satisfies φ=λg/2+δ. Here, 0≤δ≤λg/20 is satisfied, and the diameter φ is equal to or slightly longer than λg/2.

A length L (see FIG. 3B) of the dielectric resonator (the dielectric 11) may be calculated as L=λg/2+δ′, where λg is the guide wavelength of the dielectric 11, and 0≤δ′≤λg/10 is satisfied. A desired length L of the dielectric resonator (the dielectric 11) is expressed by Eq. (2).

$$L = λ g / 2 + {δ}^{′} \qquad Eq . ( 2 )$$

The representative dimension of the length L of the dielectric resonator (the dielectric 11) is about δ′=λg/10. Therefore, the length L is equal to or slightly longer than λg/2.

### (Reflection Antenna)

As shown in FIGS. 1 to 3, the remote plasma device 1 further includes a metal rod reflection antenna 28 formed in the dielectric 11 to be in parallel to the gas line 12c. The reflection antenna 28 is disposed on the opposite side of the slot antenna 14 with the gas line 12c interposed therebetween. As shown in FIG. 3A, the cross section of the reflection antenna 28 has a perfect circular shape. However, the cross section of the reflection antenna 28 does not necessarily has a perfect circular shape, and may have another shape such as a plate shape, a quadrilateral columnar shape, or the like.

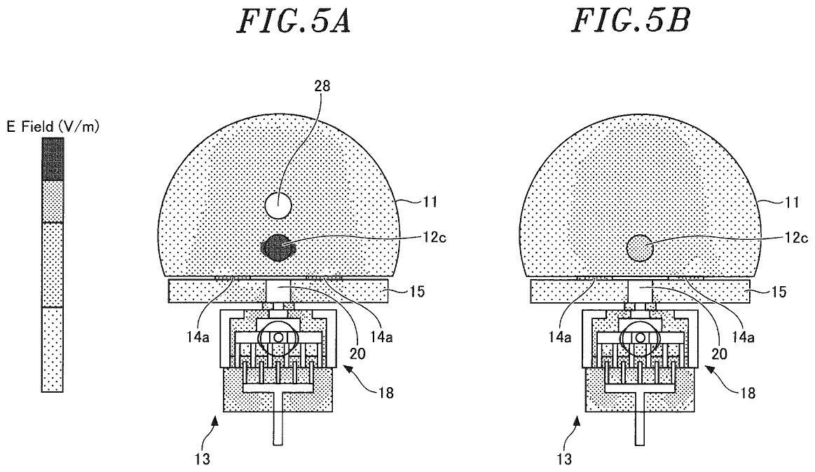

The reflection antenna 28 is disposed at a position parallel to the central axis ax of the gas line 12c (the plasma generation space). FIGS. 5A and 5B show examples of the results of an electric field simulation in the dielectric 11 at the time of ignition according to an embodiment. FIG. 5A shows an electric field state in the dielectric 11 at the time of ignition in the case where the reflection antenna 28 is disposed at a position parallel to the gas line 12c, and FIG. 5B shows an electric field state in the dielectric 11 at the time of ignition in the case where the reflection antenna 28 is not disposed.

As shown in FIG. 5A, the electric field vector of the microwaves radiated from the slot 14a of the slot antenna 14 is reflected by the reflection antenna 28, and reflected microwaves are strengthened with the microwaves radiated from the slot 14a. Accordingly, the microwaves having the same phase can be supplied to the gas line 12c. Hence, the microwave power can be efficiently supplied to the plasma generation space, and the ignition in the gas line 12c can be promoted.

On the other hand, when the reflection antenna 28 is not disposed as shown in FIG. 5B, the electric field in the gas line 12c is lower than the electric field in the gas line 12c in the case where the reflection antenna 28 is disposed as shown in FIG. 5A. Further, in order to reduce attenuation of the electric field that has reflected the reflection antenna 28, it is preferable that the reflection antenna 28 is disposed closest to the gas line 12c. The reflection antenna 28 may be close to the gas line 12c by a distance of 2 mm to 3 mm. The reflection antenna 28 is preferably, but not necessarily, parallel to the gas line 12c.

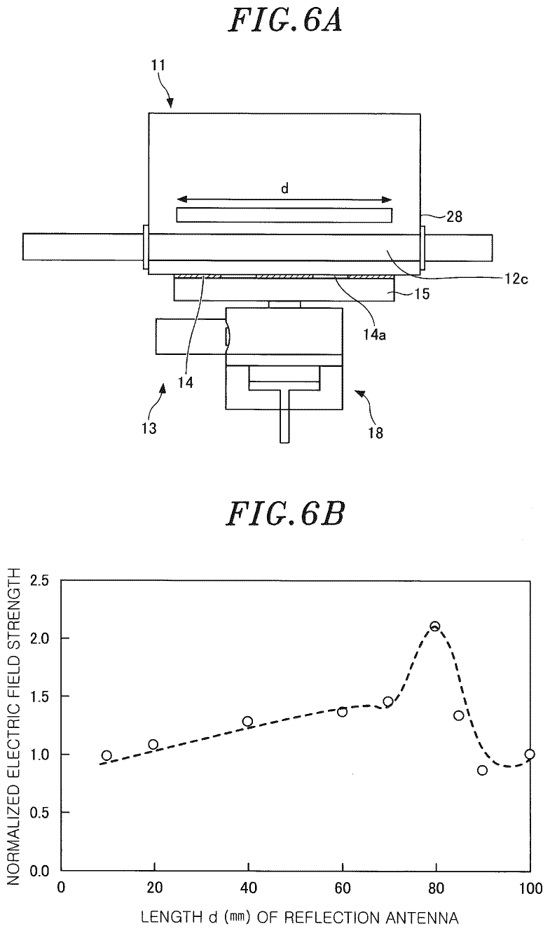

A length d (see FIG. 6A) of the reflection antenna 28 will be described with reference to the graph in FIG. 6B. FIG. 6B shows an example of a simulation result of the relationship between the length of the reflection antenna 28 and the electric field strength according to one embodiment.

In this simulation, the thickness of the reflection antenna 28 in the radial direction was assumed to be negligible, and the relationship between the length of the reflection antenna 28 and the electric field strength was determined. In the simulation conditions, 860 MHz microwaves were supplied to the plasma processing apparatus 100 shown in FIG. 1. In FIG. 6B, the horizontal axis represents the length d (mm) of the reflection antenna 28, and the vertical axis represents the normalized electric field strength. The normalized electric field strength indicates the maximum value of the electric field in each cross section from the right end to the left end of the gas line 12c. As shown in FIG. 6B, the normalized electric field strength was maximum when the length d of the reflection antenna 28 was approximately 80 mm.

Therefore, the desired length d of the reflection antenna 28 is expressed by Eq. (3).

$$d = 80 mm = λ g / 2 + {δ}^{″} \qquad Eq . ( 3 )$$

Here, −λg/10≤δ″≤0 is satisfied. Therefore, the length d of the reflection antenna 28 is equal to or slightly shorter than λg/2. Accordingly, the length d of the reflection antenna 28 is equal to or less than the length L (see FIG. 3B) of the dielectric resonator (the dielectric 11).

### (Modification of Reflection Antenna)

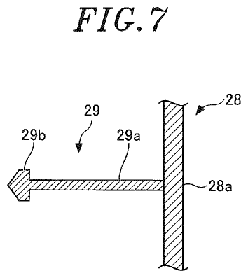

A modification of the reflection antenna 28 will be described with reference to FIG. 7. FIG. 7 shows the modification of the reflection antenna 28 according to an embodiment. The reflection antenna 28 shown in FIG. 7 includes a protrusion 29 protruding toward the gas line 12c from a main body 28a of the reflection antenna 28 that is formed in the dielectric 11 to be in parallel to the gas line 12c.

The protrusion 29 of the reflection antenna 28 has a rod-shaped member 29a made of a conductor and a head 29b formed at the tip end of the rod-shaped member 29a.

By providing the protrusion 29 at the reflection antenna 28, the electric field vector of the microwaves radiated from the slot antenna 14 is reflected at the protrusion 29, and reflected microwaves are strengthened with the microwaves radiated from the slot 14a so that the microwaves of the same phase can be supplied to the gas line 12c. Accordingly, the microwave power can be efficiently supplied to the plasma generation space, and the ignition in the gas line 12c can be promoted.

As described above, in accordance with the remote plasma device 1 of the present embodiment, the microwaves have a short wavelength and, thus, the remote plasma device 1 can be scaled down. Further, it is possible to manufacture the remote plasma device 1 having high power transmission efficiency and high ignition performance by allowing the dielectric 11 where the gas line 12c is formed to function as a dielectric resonator and providing the reflection antenna 28 having an ignition promoting structure near the dielectric body 11. Specifically, the dielectric 11 having a defective cylindrical shape is directly attached to the electromagnetic wave supply part 13 in order to transmit the energy to the plasma, and the reflection antenna 28 is installed near the plasma generation space in the gas line 12c in order to promote ignition.

By employing a resonant structure in the dielectric 11 where the gas line 12c is formed, plasma can be efficiently generated in the plasma generation space in the gas line 12c. Further, in the case of a conventional microwave plasma source, coating damage may occur depending on process conditions due to the electric field concentration at the boundary between the dielectric and the metal part of the chamber opening. On the other hand, in accordance with the remote plasma device 1 of the present embodiment, the damage problem can be eliminated by producing plasma in the cylindrical space of the gas line 12c that is directly formed at the dielectric 11. In terms of the plasma ignition, it is possible to promote ignitability by utilizing the reflected radiation of the microwaves in the reflection antenna 28.

Further, since the remote plasma device 1 itself is scaled down, the remote plasma device 1 can be assembled to a predetermined space of the plasma processing apparatus 100. Accordingly, there are no restrictions on the remote plasma device 1 that can be applied to the plasma processing apparatus 100. In addition, the manufacturing cost of the remote plasma device 1 can be reduced.

The above-described embodiments include the following aspects, for example.

### Appendix 1

A remote plasma device comprising:
a housing made of a metal;
a dielectric disposed to fill the housing;
a gas supply port disposed at the housing, and configured to supply a gas into the housing;
a gas exhaust port disposed at the housing, and configured to discharge the gas from the housing;
a gas line that is formed in the dielectric and connects the gas supply port and the gas discharge port; and
an electromagnetic wave supply part disposed at the housing, and configured to supply electromagnetic waves into the housing and produce plasma in the gas line.

### Appendix 2

The remote plasma device of Appendix 1, further comprising:
a metal reflection antenna formed at the dielectric to be in parallel to the gas line.

### Appendix 3

The remote plasma device of Appendix 1 or 2, wherein an inner shape of the housing has an imperfect cylindrical shape in which a flat surface is formed on a part of a side surface of a cylindrical shape.

### Appendix 4

The remote plasma device of any one of Appendices 1 to 3, wherein the dielectric has a structure that resonates with the electromagnetic waves at a frequency supplied by the electromagnetic wave supply part.

### Appendix 5

The remote plasma device of any one of Appendixes 1 to 4, wherein a diameter φ of the dielectric is calculated as φ=λg/2+δ, where λg is a guide wavelength in the dielectric, and 0≤δ≤λg/20 is satisfied.

### Appendix 6

The remote plasma device of any one of Appendices 1 to 5, wherein a length L of the dielectric is calculated as L=λg/2+δ′, where λg is a guide wavelength in the dielectric, and 0≤δ′≤λg/10 is satisfied.

### Appendix 7

The remote plasma device of Appendix 2, wherein a length d of the reflection antenna is calculated as d=λg/2+δ″, where λg is a guide wavelength in the dielectric, and −λg/10≤δ″≤0 is satisfied.

### Appendix 8

The remote plasma device of Appendix 7, wherein the length d of the reflection antenna is smaller than or equal to a length L of the dielectric.

### Appendix 9

The remote plasma device of any one of Appendices 1 to 8, wherein the gas line is disposed at a central axis of the dielectric.

### Appendix 10

The remote plasma device of any one of Appendices 1 to 9, wherein the electromagnetic wave supply part supplies the electromagnetic waves into the housing via a slot antenna.

### Appendix 11

The remote plasma device of Appendix 10, wherein the electromagnetic wave supply part includes a comb-shaped resonator, and supplies the electromagnetic waves into the housing via the comb-shaped resonator and the slot antenna.

### Appendix 12

The remote plasma device of Appendix 10 or 11, wherein the slot antenna is disposed along a flat surface formed at the dielectric.

### Appendix 13

The remote plasma device of Appendix 10, wherein a metal reflection antenna formed at the dielectric to be in parallel to the gas line is disposed on an opposite side of the slot antenna with the gas line interposed therebetween.

### Appendix 14

The remote plasma device of any one of Appendices 1 to 13, wherein the electromagnetic wave supply part supplies, as the electromagnetic waves, microwaves having a frequency of 300 MHz to 3 THz.

### Appendix 15

The remote plasma device of Appendix 2, wherein the reflection antenna includes a protrusion protruding toward the gas line.

### Appendix 16

A plasma processing apparatus comprising:
a plasma processing chamber;
a placing table disposed in the plasma processing chamber and on which a substrate to be processed is placed; and
the remote plasma device disclosed in any one of Appendices 1 to 3 and configured to supply active species of a gas into the plasma processing chamber.

It should be noted that the remote plasma device and the plasma processing apparatus according to the embodiments of the present disclosure are illustrative in all respects and are not restrictive. The above-described embodiments can be variously changed and modified without departing from the scope of the appended claims and the gist thereof. The above-described embodiments may include other configurations without contradicting each other and may be combined without contradicting each other.

1. A remote plasma device comprising:
a housing made of a metal;
a dielectric disposed to fill the housing;
a gas supply port disposed at the housing, and configured to supply a gas into the housing;
a gas exhaust port disposed at the housing, and configured to discharge the gas from the housing;
a gas line that is formed in the dielectric and connects the gas supply port and the gas discharge port; and
an electromagnetic wave supply part disposed at the housing, and configured to supply electromagnetic waves into the housing and produce plasma in the gas line.

2. The remote plasma device of claim 1, further comprising:
a metal reflection antenna formed at the dielectric to be in parallel to the gas line.

3. The remote plasma device of claim 1, wherein an inner shape of the housing has an imperfect cylindrical shape in which a flat surface is formed on a part of a side surface of a cylindrical shape.

4. The remote plasma device of claim 1, wherein the dielectric has a structure that resonates with the electromagnetic waves at a frequency supplied by the electromagnetic wave supply part.

5. The remote plasma device of claim 1, wherein a diameter φ of the dielectric is calculated as φ=λg/2+δ, where λg is a guide wavelength in the dielectric, and 0≤b≤λg/20 is satisfied.

6. The remote plasma device of claim 1, wherein a length L of the dielectric is calculated as L=λg/2+δ′, where λg is a guide wavelength in the dielectric, and 0≤δ′≤λg/10 is satisfied.

7. The remote plasma device of claim 2, wherein a length d of the reflection antenna is calculated as d=λg/2+δ″, where λg is a guide wavelength in the dielectric, and −λg/10≤δ″≤0 is satisfied.

8. The remote plasma device of claim 7, wherein the length d of the reflection antenna is smaller than or equal to a length L of the dielectric.

9. The remote plasma device of claim 1, wherein the gas line is disposed at a central axis of the dielectric.

10. The remote plasma device of claim 1, wherein the electromagnetic wave supply part supplies the electromagnetic waves into the housing via a slot antenna.

11. The remote plasma device of claim 10, wherein the electromagnetic wave supply part includes a comb-shaped resonator, and supplies the electromagnetic waves into the housing via the comb-shaped resonator and the slot antenna.

12. The remote plasma device of claim 10, wherein the slot antenna is disposed along a flat surface formed at the dielectric.

13. The remote plasma device of claim 10, wherein a metal reflection antenna formed at the dielectric to be in parallel to the gas line is disposed on an opposite side of the slot antenna with the gas line interposed therebetween.

14. The remote plasma device of claim 1, wherein the electromagnetic wave supply part supplies, as the electromagnetic waves, microwaves having a frequency of 300 MHz to 3 THz.

15. The remote plasma device of claim 2, wherein the reflection antenna includes a protrusion protruding toward the gas line.

16. A plasma processing apparatus comprising:
a plasma processing chamber;
a placing table disposed in the plasma processing chamber and on which a substrate to be processed is placed; and
the remote plasma device disclosed in claim 1 and configured to supply active species of a gas into the plasma processing chamber.
